(19) United States
(12) Patent Application Publication
(10) Pub. No.: US 2011/0317358 A1
(43) Pub. Date: Dec. 29, 2011

(54) Structural Improvement of Screwless Fixing Component

(76) Inventor: Li Shih-Wun, Taoyuan County (TW)

(21) Appl. No.: 12/823,139

(22) Filed: Jun. 25, 2010

(51) Int. Cl. H05K 7/12

(52) U.S. Cl. 361/679.58

(57) ABSTRACT

This invention provides a structural improvement for screwless fixing component that contains a positioning board installed in the long hole of side rack of host computer; a sliding base slotting through a positioning board, the sliding base includes bottom base and locking section; the symmetrical locking section is installed on the bottom base; a spring, one end is installed on the locking section of sliding base; a cap housing installed on the other end of outer side of locking section of sliding base and spring, its interior is installed with concaving section, the interior of concaving section is installed with axial rod having thread section. Except for free of tool, the axial rod of cap housing is inserted through screw hole of driver installed in host computer for quick screwing compression or loosening.

### BACKGROUND OF THE INVENTION

(a) Field of the Invention

The present invention relates to the improvement of a kind of screwless fixing structure, particularly a kind of fixing structure for sliding the driver into the host computer to the position and fix the driver without the need of any tool.

(b) Description of the Prior Art

Please refer to the illustration of FIGS. 1 and 2, wherein the cross-sectional diagram and 3D assembly for conventional product is shown. In general, in order for a computer to connect with driver 1, a protruding support 22 is installed on the side rack 21 of the host 2, whereas the support 22 is installed with a set or two sets of long holes 23, and support 22 is for providing support for driver 1 (such as DVD driver, hard disk driver, or floppy disk driver, etc.) so that it will not fall off, and support 22 is installed with multiple long holes 23, during assembly the driver 1 is inserted through the support 22 of side rack 21 so that when driver 1 is moved forward or backward to the most suitable position before a screw 12 is inserted through the long hole 23 of side rack 21. However, during assembling prior art special screwdriver has to be prepared as a tool for loosening or tightening screw 12. In addition, the space inside host 2 is quite narrow and tool is often too small to enter. Except driver 1 is not able to remove or fixed, tightening screw by force at slanting angle could easily result in slipping and hurting of the body; or the head of screw 12 could be damaged because of evenly applied force, resulting in driver 1 unable to be taken down or unable to be fixed on side rack 21; again, the screw 12 used in prior art is quite small, slight mistake screw 12 could fall inside the host 12 or onto the motherboard, causing screw 12 to be lost or host 2 to be short circuited. In view of this, the inventor of present invention takes this point into consideration in the design with the final result of improvement of screwless fixing structure that could quickly fix driver 1 directly onto side rack 21 of host 2 without having to use any tool.

### SUMMARY OF THE INVENTION

To resolve the inadequacy of existing technology described above, the purpose of the present invention is to provide a kind of structural improvement of screwless fixing component in the hope of overcoming the difficulty in existing technology.

To achieve the above purpose, the present invention is to provide a structural improvement of a kind of screwless fixing component including:

A positioning board, installed on the long hole position of the side rack of the computer, wherein its center is installed with a long protruding base, the center of the protruding base is installed with a long through hole;

A sliding base, inserted into the positioning board, the sliding base contains a base, a locking section; the center of the base is installed with a bottom hole, the top of both sides of which are installed with a locking protrusion corresponding to positioning board, the symmetrical locking section is installed and protruding at the top of bottom base, wherein the center is installed with U-shape central base having hollow interior, the top of the central base is installed with cone shape clamping hole connecting to hollow interior and bottom hole, the two outer sides of central base are installed with exterior spring section having sliding guide surface;

A spring, which is a compressed spring, one end of which is slotting on the locking section of sliding base;

A cap housing, installed on the outer side of locking section and the other end of spring, wherein the interior is installed with cone shape concaving section, inside the concaving section is installed with axial rod having end thread section, the axial rod is slotting on the hollow interior of the locking section of sliding base.

Through this design, there is no need to use tool and screw and the axial rod of cap housing can be slotted on sliding base, and the locking section and the screw hole on the side of driver installed in the side rack of the host computer can be quickly compressed or loosen, which is obvious to see its benefits.

### BRIEF DESCRIPTION OF THE DRAWINGS

FIG. 1 is 3D blowup diagram of prior art.

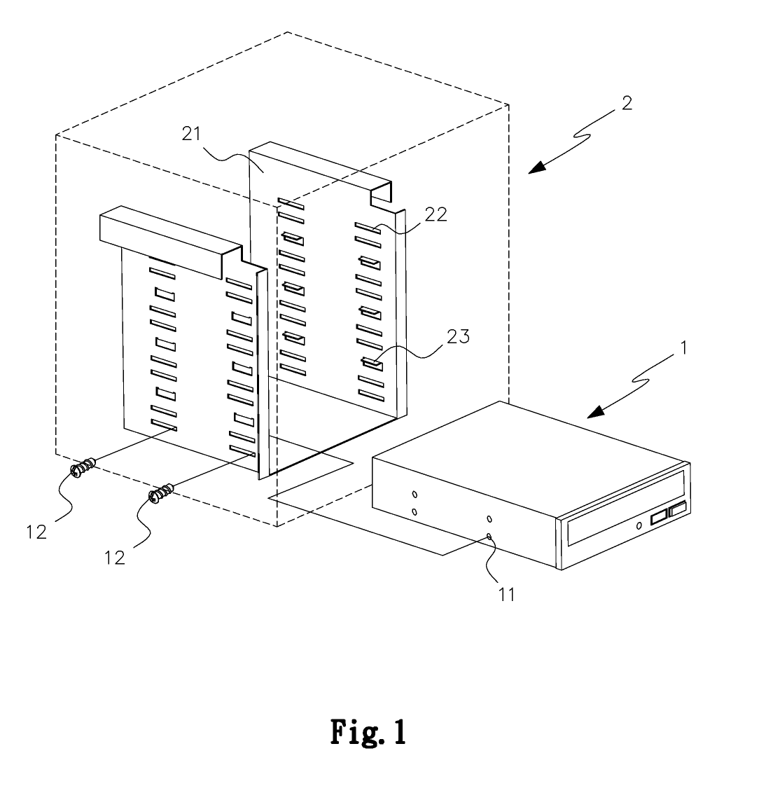

FIG. 2 is 3D assembly of prior art.

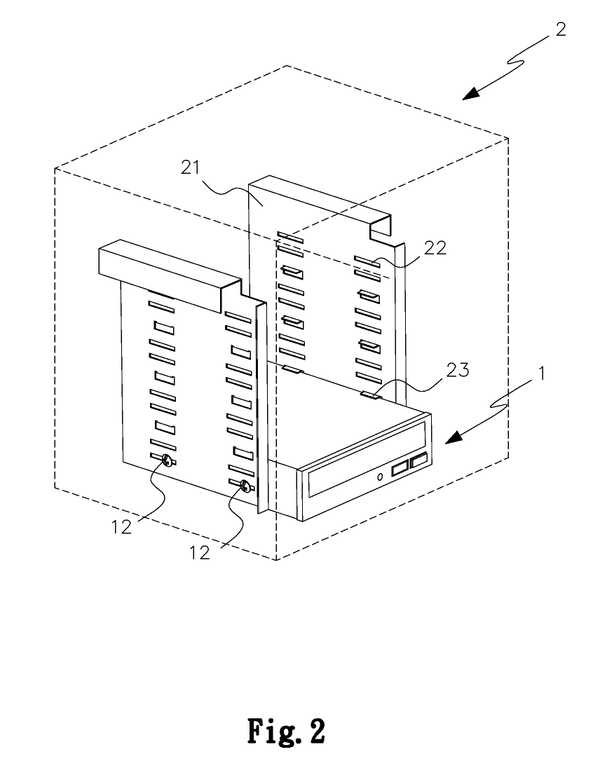

FIG. 3 is the 3D blowup diagram of present invention.

FIG. 4 is the 3D assembly diagram of the present invention.

FIG. 5 is the cross-sectional diagram of the assembly of the present invention.

FIG. 6 is the 3D diagram showing the action of side board of host computer and the driver.

FIG. 7 is the 3D blowup diagram of the action of the present invention and the driver.

FIG. 8 is the 3D assembly diagram of the action of the present invention and the driver.

### DESCRIPTION OF MAIN COMPONENT SYMBOLS

### Prior Art

1: Driver
11: Screw hole
12: Screw
2: Host computer
21: Side rack
22: Supporting rack
23: Long hole

### Present Invention

3: Positioning board
31: Protruding base
32: Long through hole
4: Cap housing
40: Concaving section
41: Axial rod
42: Thread section
5: Spring
6: Sliding base
60: Bottom base
600: Locking section
601: Central base
602: Exterior spring section
603: Sliding guide surface
604: Sliding groove
61: Locking protrusion
62: Clamping hole
63: Hollow interior
64: Bottom hole

### DETAILED DESCRIPTION OF THE PREFERRED EMBODIMENTS

To facilitate the reviewing panel in understanding of the features, content, and advantages of the present invention, the detailed description of the present invention is explained below with illustrations together with the expressed form of its embodiments. The aim is just for the use of illustration and auxiliary explanation and not necessary in the actual proportion and precise configuration after the implementation of the present invention. Hence the focus of the claim of the actual implementation of the present invention should not be restricted to the ratio and configuration of the attached illustration.

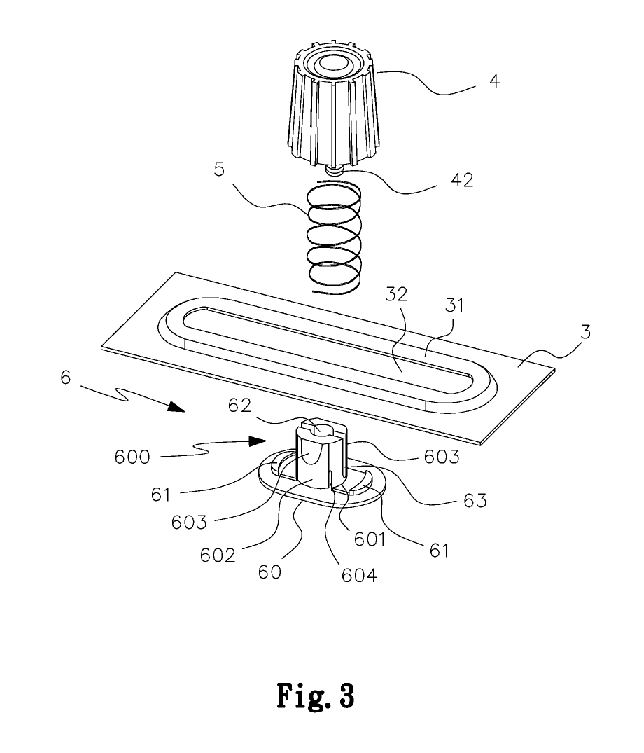

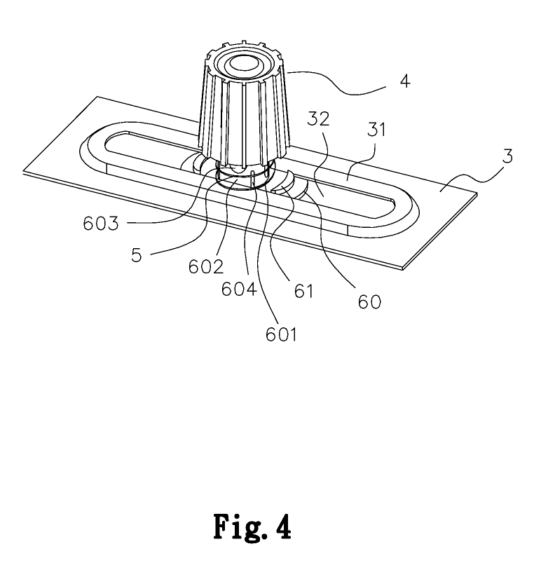

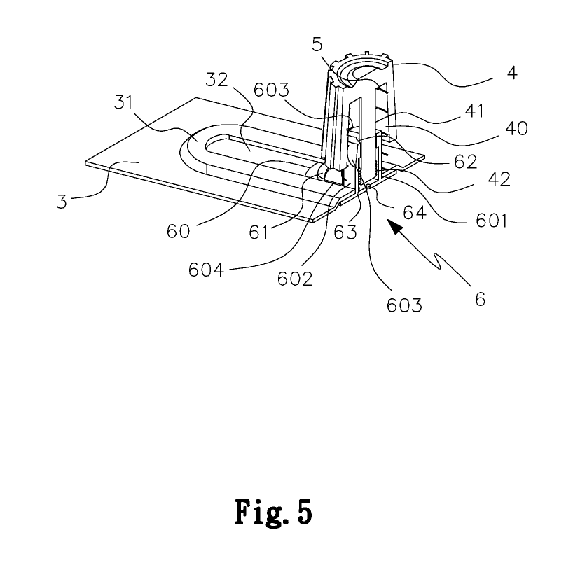

Please refer to the illustrations of FIGS. 3, 4, and 5, which shows the 3D blowup diagram, 3D assembly diagram, and cross-sectional assembly of the present invention in one of the preferred embodiment of present invention for the structural improvement of fixed component, including a positioning board 3, a sliding base 6, a spring 5, a cap housing 4.

The positioning board 3 stated previously can be installed in the long hole 23 of the side rack 21 of the computer 2, the center of the positioning board 4 is installed with a long protruding base 31 ad its center is installed with long hole 32.

The sliding base 6 stated previously is installed on positioning board 3, the sliding base 6 contains a bottom base 60, a locking section 600; the shape of bottom base 60 corresponds to the protruding base 31 of positioning board 3, for providing it to slide on protruding base 31; the center of the bottom base 60 is installed with a bottom hole 64, the top of both sides of which is installed with locking protrusion 51 in order to correspond to the long through hole 32 at center of protruding base 31 of positioning board 3 and further provides bottom base 60 with the function of non-shifting sliding on protruding base 31 of positioning board 3; and the symmetrical and upright cone locking section 600 is installed on bottom base 60, in between is installed with sliding groove 604, the locking section 600 is penetrating through long through hole 32 of protruding base 31 of positioning board 3; the center of locking section 600 is installed with U-shape central base 601 having hollow center 63; the top of central base 601 is installed with separated cone clamping hole 62, said clamping hole 62 is connected to the hollow interior 63 inside locking section 600 and bottom hole 64 of bottom base 60; both outer sides of central base 601 extend downward from top are installed slantingly with outer spring section 602, the direction of outer spring section 602 is in perpendicular position to lock protrusion 61 of bottom base 60. In order for locking section 600 to easily pierce through long through hole 32 of protruding base 31 of positioning board 3, the outside of spring section 602 is installed with slanting gliding surface 603.

Spring 5 stated previously is a compressed spring, with one end installed on locking section 600 of gliding base.

The cap housing 4 stated previously is installed at the other end of the outside of locking section 600 of bottom base 6 and spring 5; inside cap housing 4 is installed with concaving section 40 in cone shape for action with gliding base 6; inside the concaving section 40 is installed with axial rod 41 of end thread section 42, said axial rod 41 can be slotted on the clamping hole 62 of locking section 600, hollow interior 63, and bottom hole 64 of bottom base 60.

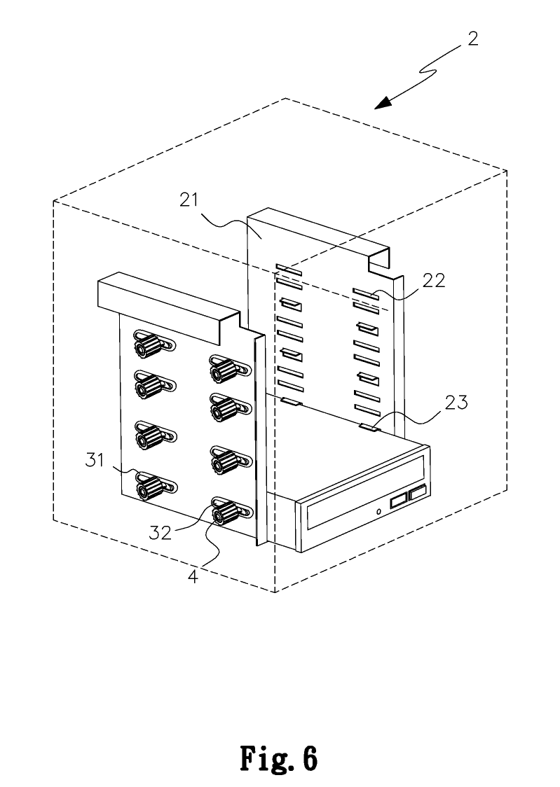

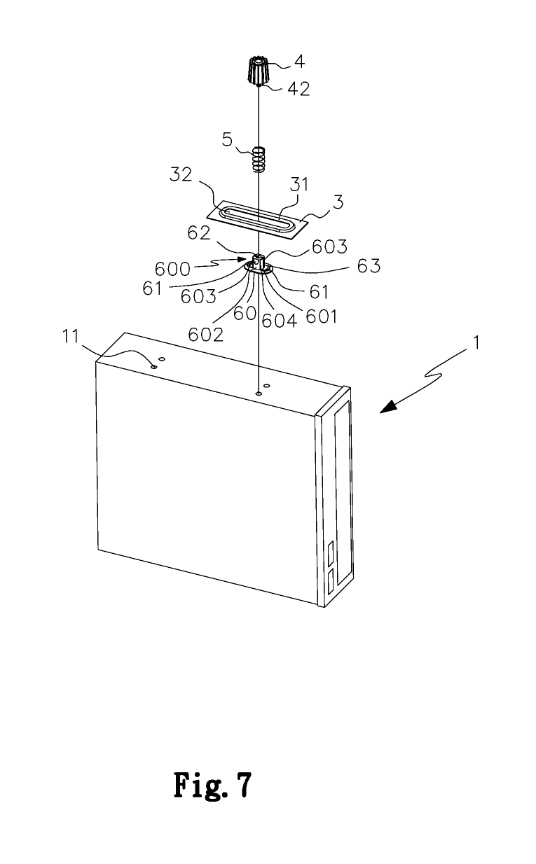

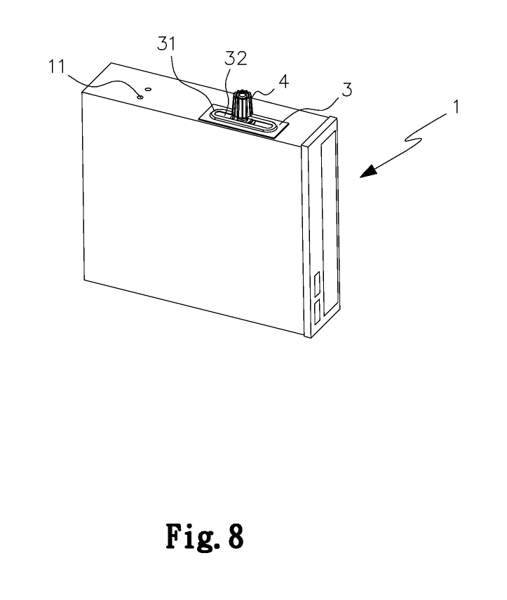

Please refer to the illustration of FIG. 6, FIG. 7, and FIG. 8. The illustration shows the 3D diagram of the present invention working with the sideboard of the host and driver, the 3D blowup cross-sectional diagram of the present invention working with the driver, and the 3D assembly diagram. The present invention does not need to damage the side rack 11 of the host computer 2. It can be assembled directly onto the side rack 11 of the host computer 2 and located on the long hole 23 on supporting rack 22, the bottom base 60 of sliding base 6 is installed at the bottom of protruding base 31 of positioning board 3 for sliding. When the locking section 600 on the sliding base 6 is to be installed on the protruding base 31, the locking section 600 can easily penetrate the long through hole 63, due to the external spring section 602 of the out-slanting locking section 600 is installed with slanting guide surface 603 and the width of the top section of top-narrow bottom-broad cone shape locking section 600 is smaller than the long through hole 32 while the width of the lower section is larger than the long through hole 32. When the lower section of the locking section 600 passes through long through hole 32, the structure of the outer spring section 602 is subjected to compression and withdraw. When the bottom of external spring section 602 passes through the long through hole, it recovers to original position. The lower section of the external spring section 602 will clamp to the outer side of long through hole 32 of the protruding base 31. The clamping protrusion 61 on both sides of bottom base 60 will clamp on the long through hole 32 in order to provide non-shifting glide. The locking section 600 of the slide base 6 will also be locked in the sliding groove 604 formed between the bottom base 60 and the locking section 600 for stable sliding and the action of protruding base 31 of positioning board 3, due to the width of its external spring section 602 is larger than the long through hole 32. Also, the cap housing 4 is slotted on the locking section 600 of the sliding base 6. As the center of cap housing 4 is installed with axial rod 41 of end thread section 42, only the axial rod 41 is required to insert into the cone clamping hole 62 at the top of locking section 600 in order for cap housing 4 to be locked with sliding base 6. As the clamping hole 62 is showing top-broad bottom-narrow cone-shaped hole and subject to the separation of U-shape central base 601 presenting two opposing sides with elasticity, the diameter of its top is greater than the thread section 42 while the diameter of its bottom is smaller than the thread section 42, hence when the cap housing 4 is clamped into sliding base 6 the thread section 42 will first act on the cone-shape clamping hole 62, and the U-shape central base 61 will be spread open until the thread section 42 at the end of said axial rod 41 passes through clamping hole 62 and return to original shape. At this time, the thread section 42 with larger diameter than axial rod 41 will in turn enter the hollow interior 63 of the locking section 600 and become fixed to locking state. Also, spring 5 is installed between sliding base 6 and cap housing 4. When screw rod 41 is not acting on driver 1, the cap housing 4 is pushed up through compression spring 5. The thread section 42 of axial rod 41 is installed against the top of hollow interior 63, and also the diameter of said thread section 42 is larger than the hole below the cone clamping hole 62 of the locking section 600, hence the thread section 42 will not drop out of said clamping hole 62.

When using the present invention, it is only required to push down cap housing 4 directly. At this time, spring 5 will be compressed while at the same time press down. The thread section 42 of axial rod 41 will pass through the bottom hole 64 of bottom base 60. The bottom hole in turn passes through the long hole 23 originally installed on the side rack 21 of host computer 2. Therefore, thread section 42 can be locked directly to the screw hole 11 of the driver 1. The locking section 600 of sliding base 6 will compress inward against the protruding base 31 on positioning board 3, due to the cone-shaped concaving section 40 of cone-shaped cap housing. Driver 1 at the same time will be pulled in the direction of bottom base 60 synchronously and clamp to position. If the present invention has to be loosen up for sliding, it is only required to rotate cap housing 4 in the reverse direction for the thread section 42 to depart screw hole 11 of driver 1. Cap housing 4 subjecting to the recovering force of spring 5 will spring back together with axial rod 41, and thread section 42 will return to original position against the internal top section of hollow interior 63 of the locking section 600. Driver 1 can be taken out when the exterior spring section 600 of locking section 600 of sliding base 6 does not compress against sliding base 60, or sliding base 6, spring 5 and cap housing 4 can slide to suitable position together with the movement of driver 1 when it is loosen but not leaving the screw hole 11 of driver 1.

With this design, the present invention can be free of using tool and screw to slot axial rod 41 of cap housing 4 onto sliding base 6 and quickly tighten or loosen the screw hole 11 beside driver 1 installed in the side rack 21 of host computer 2 and locking section 600 and further does not need to damage the side rack 21 of host computer 2. Hence the operation is easy and meets the requirement of increased benefits.

Summarizing above it can be known that the present invention has achieved the performance it intended to improve and also beyond the thinking of experts mastering the art. Also, the present invention has never been revealed before. The advance and practicality it posses has obviously meets the prerequisite for application of invention patent. I hereby appreciate your consideration of granting this application of patent for encouraging the invention.

The embodiments mentioned above are intended only for explanation of the thinking and features of the present invention. The purpose is for experts mastering this art to understand the content of the present invention for their implementation and by no means limited to the focus of the claims of the present invention. All equalizing change or modification to the spirit revealed in this invention should still be covered in the focus of the claims of the present invention.

What is claimed is:

1. A kind of structural improvement screwless fixing component, including:
A positioning board, which is installed on the long hole of the side rack of a host computer, wherein the center is installed with a long protruding base, and the center of the long protruding base is installed with a long through hole;
A sliding base, slotting on positioning board, the sliding base includes a bottom base, a locking section; the center of bottom base is installed with a bottom hole and is a protruding base corresponding to positioning board, the top of the two sides of bottom base is installed with locking protrusion of long through hole of corresponding positioning base, the symmetrical locking section is installed on the protruding base of the positioning board, its center is installed with U-shape central base having hollow interior, the top of central base is installed with a separation clamping hole, and clamping is for connection through hollow interior and bottom hole of the bottom base, both sides of central base is installed with exterior spring section having sliding guide surface on the outside:
A spring, one end is slotted on the locking section of sliding base;
A cap housing, installed on outer side of the locking section and the other end of the spring, said cap housing is installed with a cone shape concaving section, inside the concaving section is installed with axial rod having thread section, said axial rod is slotted on the hollow interior of locking section.

2. As the structural improvement of screwless fixing component stated in claim 1, wherein a sliding groove is installed between the bottom base of the sliding base and locking section.

3. As the structural improvement of screwless fixing component stated in claim 2, wherein the spring is a compressed spring.

4. As the structural improvement of screwless fixing component stated in claim 3, wherein the clamping hole is in cone shape.

5. As the structural improvement of screwless fixing component stated in claim 4, wherein the direction of external spring section is perpendicular to the locking protrusion of bottom base.

6. As the structural improvement of screwless fixing component stated in claim 6, wherein the locking section of sliding base is showing top-narrow and bottom-broad cone.

7. As the structural improvement of screwless fixing component stated in claim 6, wherein the sliding guide surface of exterior spring section is showing slanting shape.

8. As the structural improvement of screwless fixing component stated in claim 7, wherein the exterior spring section is slanting from the top section of two sides of central base and extends to two sides.
